(19) United States
(12) Patent Application Publication
(10) Pub. No.: US 2023/0395622 A1
(43) Pub. Date: Dec. 7, 2023

(54) PHOTOELECTRIC CONVERSION APPARATUS AND EQUIPMENT

(71) Applicant: CANON KABUSHIKI KAISHA, Tokyo (JP)

(72) Inventors: DAIKI SHIRAHIGE, Kanagawa (JP); SHUHEI HAYASHI, Kanagawa (JP); HAJIME IKEDA, Kanagawa (JP); KOJI HARA, Chiba (JP)

(21) Appl. No.: 18/328,672

(22) Filed: Jun. 2, 2023

(30) Foreign Application Priority Data
Jun. 6, 2022 (JP) 2022-091512
Jun. 6, 2022 (JP) 2022-091514

(51) Int. Cl. H01L 27/146

(52) U.S. Cl. CPC H01L 27/14614; H01L 27/14645

(57) ABSTRACT

A photoelectric conversion apparatus includes a first component including a first semiconductor substrate having a first surface and a second surface opposite the first surface, a photoelectric conversion element configured to receive light from the first surface, a first semiconductor region, a transfer gate disposed on the second surface and configured to transfer a charge from the photoelectric conversion element to the first semiconductor region, and a first gate insulator film disposed between the second surface and the transfer gate, and a second component stacked on the first component and including a second semiconductor substrate having a third surface and a fourth surface opposite the third surface, an amplifier transistor including a gate connected to the first semiconductor region, and a second gate insulator film between the gate and the third surface. The first gate insulator film and the second gate insulator film are different in relative permittivity.

### BACKGROUND OF THE INVENTION

### Field of the Invention

The present disclosure relates to a photoelectric conversion apparatus and equipment.

### Description of the Related Art

In order to realize a higher density of pixels of a photoelectric conversion apparatus, a first semiconductor substrate includes photoelectric conversion units of the pixels, and a second semiconductor substrate includes pixel circuits of the pixels according to WO 2019/130702. According to WO 2019/130702, the first semiconductor substrate and the second semiconductor substrate are stacked. Further, according to WO 2019/130702, a gate insulator film of a transfer transistor of the first semiconductor substrate and a gate insulator film of an amplifier transistor of the second semiconductor substrate have a different film thickness from each other.

The technique discussed in WO 2019/130702 still has possibilities of further developments in relative permittivity of the gate insulator film of the first semiconductor substrate or in reduction of power consumption of pixel read circuits while realizing high saturation charge of the photoelectric conversion units.

### SUMMARY OF THE INVENTION

According to an aspect of the present disclosure, a photoelectric conversion apparatus includes a first component including a first semiconductor substrate having a first surface and a second surface opposite the first surface, a photoelectric conversion element configured to receive light from the first surface, a first semiconductor region, a transfer gate disposed on the second surface and configured to transfer a charge from the photoelectric conversion element to the first semiconductor region, and a first gate insulator film disposed between the second surface and the transfer gate, and a second component stacked on the first component and including a second semiconductor substrate having a third surface and a fourth surface opposite the third surface, an amplifier transistor including a gate connected to the first semiconductor region, and a second gate insulator film between the gate and the third surface. The first gate insulator film and the second gate insulator film are different in relative permittivity.

According to another aspect of the present disclosure, a photoelectric conversion apparatus includes a first component including a first semiconductor substrate having a first surface and a second surface opposite the first surface, a photoelectric conversion element configured to receive light from the first surface, a first semiconductor region, and a transfer transistor including a transfer gate disposed on the second surface and configured to transfer a signal charge from the photoelectric conversion element to the first semiconductor region, and a second component stacked on the first component and including a second semiconductor substrate having a third surface and a fourth surface opposite the third surface, an amplifier transistor including a gate connected to the first semiconductor region and disposed on the third surface, and a reset transistor configured to reset the gate. A difference between a voltage to be applied to the transfer gate during a period of the transfer of the signal charge from the photoelectric conversion element to the first semiconductor region and a reference voltage is greater than a difference between a power supply voltage to be applied to a main node of the reset transistor and the reference voltage.

According to yet another aspect of the present disclosure, a photoelectric conversion apparatus includes a first component including a first semiconductor substrate having a first surface and a second surface opposite the first surface, a photoelectric conversion element configured to receive light from the first surface, a first semiconductor region, and a transfer transistor including a transfer gate disposed on the second surface and configured to transfer a signal charge from the photoelectric conversion element to the first semiconductor region, and a second component stacked on the first component and including a second semiconductor substrate having a third surface and a fourth surface opposite the third surface, an amplifier transistor including a gate connected to the first semiconductor region and disposed on the third surface, and a reset transistor configured to reset the gate. A first power supply voltage is applied to a main node of the reset transistor, and a second power supply voltage is applied to a main node of the amplifier transistor. A difference between a voltage to be applied to the transfer gate during a period of the transfer of the signal charge from the photoelectric conversion element to the first semiconductor region and a reference voltage is greater than at least one of a difference between the first power supply voltage and the reference voltage or a difference between the second power supply voltage and the reference voltage.

Further features of the present disclosure will become apparent from the following description of exemplary embodiments with reference to the attached drawings.

### BRIEF DESCRIPTION OF THE DRAWINGS

FIG. 1 is a diagram illustrating a structure of a photoelectric conversion apparatus.

FIG. 2 is a diagram illustrating a structure of sensor portions and a read circuit.

FIG. 3 is a cross-sectional view illustrating the photoelectric conversion apparatus.

FIG. 4 is a plan view illustrating the photoelectric conversion apparatus.

FIG. 5 is a cross-sectional view illustrating the photoelectric conversion apparatus.

FIG. 6 is a cross-sectional view illustrating the photoelectric conversion apparatus.

FIG. 7 is a plan view illustrating the photoelectric conversion apparatus.

FIG. 8 is a cross-sectional view illustrating a photoelectric conversion apparatus.

FIG. 9 is a cross-sectional view illustrating a photoelectric conversion apparatus.

FIG. 10 is a cross-sectional view illustrating a photoelectric conversion apparatus.

FIG. 11 is a cross-sectional view illustrating a photoelectric conversion apparatus.

FIG. 12 is a cross-sectional view illustrating a photoelectric conversion apparatus.

FIG. 13 is a potential diagram of a photoelectric conversion apparatus.

FIG. 14 is a potential diagram of a photoelectric conversion apparatus.

FIGS. 15A to 15C are diagrams illustrating a structure of equipment.

### DESCRIPTION OF THE EMBODIMENTS

Various exemplary embodiments will be described below with reference to the drawings.

Imaging apparatuses will be mainly described below as an example of a photoelectric conversion apparatus in the exemplary embodiments. It is to be noted that the exemplary embodiments are not limited to imaging apparatuses and are also applicable to other examples of photoelectric conversion apparatuses. Other examples include distance measurement apparatuses (apparatuses for measuring distances using focus detection or time of flight (TOF)) and light measurement apparatuses (apparatuses for measuring amounts of incident light).

Further, conductivity types of semiconductor regions and wells and dopants to be injected according to the exemplary embodiments described below are examples and are not intended to limit conductivity types or dopants. The conductivity types and the dopants according to the exemplary embodiments described below are changeable as appropriate, and in a case where a conductivity type or a dopant of a semiconductor region or a well is changed, a potential of the semiconductor region and the well are also changed as appropriate.

Conductivity types of transistors according to the exemplary embodiments described below are examples and are not intended to limit conductivity types. The conductivity types according to the exemplary embodiments described below are changeable as appropriate, and in a case where a conductivity type of a transistor is changed, potentials of a gate, a source, and a drain of the transistor are also changed as appropriate.

For a transistor configured to operate as a switch, low and high levels of a potential to be supplied to a gate of the transistor are changed to be reversed from those described in the exemplary embodiments, with a change of conductivity type. Further, conductivity types of semiconductor regions according to the exemplary embodiments described below are examples and are not intended to limit conductivity types. The conductivity types according to the exemplary embodiments described below are changeable as appropriate, and in a case where a conductivity type of a semiconductor region is changed, a potential of the semiconductor region is also changed accordingly.

Further, connection of elements of circuits will be described below in the exemplary embodiments. In this case, unless otherwise specified, the elements of interest are considered to be connected together even in a case where there is another element between the elements of interest. For example, in a case where an element A is connected to a node of a capacitor element C including a plurality of nodes and an element B is connected to the other node of the capacitor element C. Even in such a case, unless otherwise specified, the elements A and B are considered to be connected together.

Each metal member, such as a wire and a pad, described in the present specification may be made of a metal member with a single element alone or may be made of a mixture (alloy). For example, each wire to be described as a copper wire may be made of copper alone or may include mainly copper and further include other components. Further, for example, each pad to be connected to an external terminal may be made of aluminum alone or may include mainly aluminum and further include other components. The copper wires and the aluminum pads described herein are examples and may be changed to various metals. Further, the wires and the pads described herein are examples of a metal member for use in a photoelectric conversion apparatus and are also applicable to other metal members.

A first exemplary embodiment will be described below with reference to the accompanying drawings.

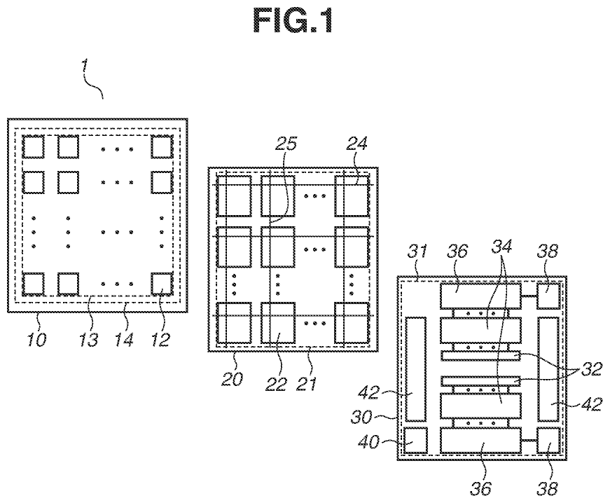

FIG. 1 illustrates an example of a schematic structure of an imaging apparatus 1 (an example of the above-described photoelectric conversion apparatuses) according to the first exemplary embodiment of the present disclosure. The imaging apparatus 1 includes three substrates (first component 10, second component 20, third component 30). The imaging apparatus 1 is an imaging apparatus having a three-dimensional structure formed by bonding three components (the first component 10, the second component 20, the third component 30) together. The first component 10, the second component 20, and the third component 30 are stacked in this order.

The first component 10 includes a plurality of sensor portions 12 configured to perform photoelectric conversion. A semiconductor substrate 14 corresponds to a specific example of a “first semiconductor substrate” according to the present disclosure. The plurality of sensor portions 12 is arranged in matrix in a pixel region 13 of the first component 10. The second component 20 includes one read circuit 22 for every four sensor portions 12. The read circuits 22 are provided on a semiconductor substrate 21 and output pixel signals based on charges output from the sensor portions 12. The semiconductor substrate 21 corresponds to a specific example of a “second semiconductor substrate” according to the present disclosure. The second component 20 includes a plurality of pixel drive lines 24 and a plurality of pixel output lines 25. The plurality of pixel drive lines 24 extends in a row direction, and the plurality of pixel output lines 25 extends in a column direction. The third component 30 includes logic circuits 32 on a semiconductor substrate 31. The logic circuits 32 process the pixel signals. The semiconductor substrate 31 corresponds to a specific example of a “third semiconductor substrate” according to the present disclosure. Each logic circuit 32 includes, for example, a vertical scan circuit 42, a column signal processing circuit 34, a horizontal scan circuit 36, and a control circuit 40.

The logic circuits 32 (specifically, the horizontal scan circuits 36) output an output voltage Vout for each sensor portion 12 to the outside. The logic circuits 32 may include, for example, a low-resistance region of silicide formed using a self-aligned silicide (salicide) process, such as CoSi₂ or NiSi, on a surface of an impurity diffusion region in contact with a source electrode and a drain electrode.

Each vertical scan circuit 42, for example, sequentially selects the plurality of sensor portions 12 in units of rows. Each column signal processing circuit 34, for example, performs correlated double sampling (CDS) processing on pixel signals output from the respective sensor portions 12 of the row selected by the vertical scan circuit 42. By performing CDS processing, for example, each column signal processing circuit 34 extracts signal levels of the pixel signals and holds pixel data corresponding to amounts of light received by the sensor portions 12. Each horizontal scan circuit 36, for example, sequentially outputs the pixel data held by the column signal processing circuit 34 to the outside. Each control circuit 40, for example, controls driving of each block (the vertical scan circuit 42, the column signal processing circuit 34, and the horizontal scan circuit 36) in the logic circuit 32.

Further, each column signal processing circuit 34 may include an analog-to-digital (AD) conversion unit for converting signals (analog signals) output from amplifier transistors AMP into digital signals.

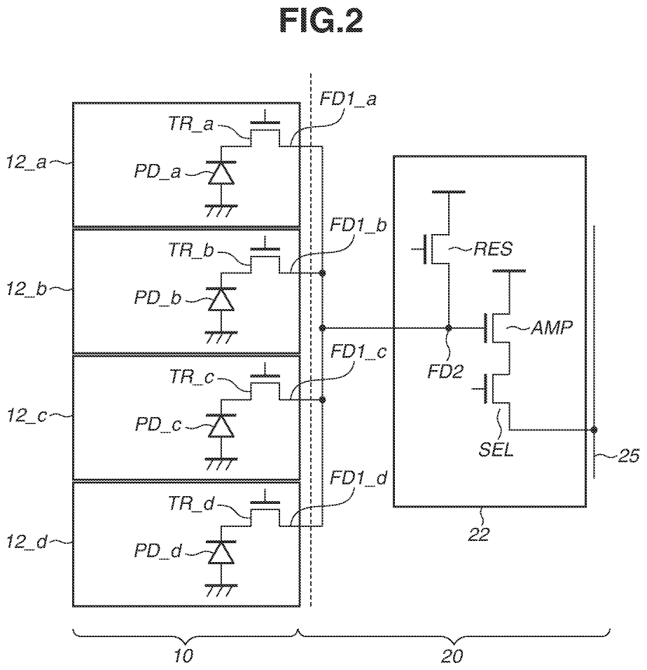

FIG. 2 illustrates an example of a structure of the sensor portions 12. Examples of the sensor portions 12 and the read circuits 22 are illustrated. Hereinafter, a case where four sensor portions 12_a to 12_d share one read circuit 22 as illustrated in FIG. 2 will be described below. As used herein, the term “share” indicates that outputs of the four sensor portions 12_a to 12_d are input to the shared read circuit 22. Hereinafter, the sensor portions 12_a to 12_d will be referred to collectively as “sensor portion 12” in describing something that is common for the sensor portions 12_a to 12_d.

The sensor portions 12 include common components to each other.

Each sensor portion 12 includes, for example, a photodiode PD, a transfer transistor TR, and a first floating diffusion (FD) node FD1. Each transfer transistor TR is electrically connected to the corresponding photodiode PD. The first FD nodes FD1 are part of a floating diffusion FD. The letters “a” to “d” are added at the ends of the reference numerals of components, such as the photodiodes PD and transfer gates, in the sensor portions 12. The read circuit 22 includes a second FD node FD2. The second FD node FD2 is another part of the floating diffusion FD and temporarily holds charges output from the photodiodes PD via the transfer transistors TR. The four first FD nodes FD1_a to FD1_d are connected to one second FD node FD2. The second FD node FD2 is an input node of the amplifier transistor AMP. Each photodiode PD corresponds to a specific example of a “photoelectric conversion element” according to the present disclosure. Each photodiode PD performs photoelectric conversion and generates charges corresponding to an amount of received light. A cathode of each photodiode PD is electrically connected to a source of the corresponding transfer transistor TR, and a potential applied to a well region is applied to an anode of the photodiode PD. In other words, the anode of the photodiode PD is electrically connected to a reference potential line (e.g., ground potential). Further, each photodiode PD is disposed inside the well region connected to the reference potential line. Drains of the transfer transistors TR are electrically connected to the floating diffusions FD, and gates of the transfer transistors TR are electrically connected to the pixel drive lines 24. Each transfer transistor TR is, for example, a complementary metal oxide semiconductor (CMOS) transistor.

The floating diffusions FD of the sensor portions 12 sharing one read circuit 22 are electrically connected together and are also electrically connected to an input end of the shared read circuit 22. The read circuit 22 includes, for example, a reset transistor RES, a selection transistor SEL, and the amplifier transistor AMP. The selection transistor SEL may be omitted as needed. A source of the reset transistor RES (the input end of the read circuit 22) is electrically connected to the floating diffusions FD. From another perspective, the source of the reset transistor RES (the input end of the read circuit 22) is electrically connected to the gate of the amplifier transistor AMP. Further, a drain of the reset transistor RES is electrically connected to a power supply line (SVDD) and a drain of the amplifier transistor AMP. A gate of the reset transistor RES is electrically connected to the corresponding pixel drive line 24 (refer to FIG. 1). A source of the amplifier transistor AMP is electrically connected to a drain of the selection transistor SEL, and the gate of the amplifier transistor AMP is electrically connected to the source of the reset transistor RES.

A source of the selection transistor SEL (an output end of the read circuit 22) is electrically connected to the corresponding pixel output line 25, and a gate of the selection transistor SEL is electrically connected to the corresponding pixel drive line 24 (refer to FIG. 1).

When a transfer transistor TR is turned into an on state, charges of the corresponding photodiode PD is transferred to the corresponding floating diffusion FD. The reset transistor RES resets a potential of the floating diffusion FD to a predetermined potential. When the reset transistor RES is turned into an on state, the potential of the floating diffusion FD is reset to a potential of the power supply line (SVDD). In other words, the reset transistor RES resets a potential of the gate of the amplifier transistor AMP to the predetermined potential. The predetermined potential is typically a voltage corresponding to a voltage obtained by subtracting a threshold voltage for the reset transistor RES from a power supply voltage SVDD. The selection transistor SEL controls output timings of pixel signals from the read circuit 22. The amplifier transistor AMP generates, as pixel signals, voltage signals corresponding to levels of charges held by the floating diffusions FD. The amplifier transistor AMP forms a source-follower type amplifier and outputs pixel signals of voltages corresponding to levels of charges generated by the photodiodes PD. When the selection transistor SEL is turned into an on state, the amplifier transistor AMP amplifies the potentials of the floating diffusions FD and outputs voltages corresponding to the amplified potentials through the corresponding pixel output line 25 to the corresponding column signal processing circuit 34. The reset transistor RES, the amplifier transistor AMP, and the selection transistor SEL are, for example, CMOS transistors.

The reset transistor RES and the selection transistor SEL may be disposed between the power supply line (SVDD) and the amplifier transistor AMP.

In such a case, the drain of the reset transistor RES is electrically connected to the power supply line (SVDD) and the drain of the selection transistor SEL. The source of the selection transistor SEL is electrically connected to the drain of the amplifier transistor AMP, and the gate of the selection transistor SEL is electrically connected to the corresponding pixel drive line 24 (refer to FIG. 1). The source of the amplifier transistor AMP (the output end of the read circuit 22) is electrically connected to the corresponding pixel output line 25, and the gate of the amplifier transistor AMP is electrically connected to the source of the reset transistor RES. Further, a transistor for changing capacitance values of the floating diffusions FD may further be included on an electric path between the reset transistor RES and the second FD node FD2.

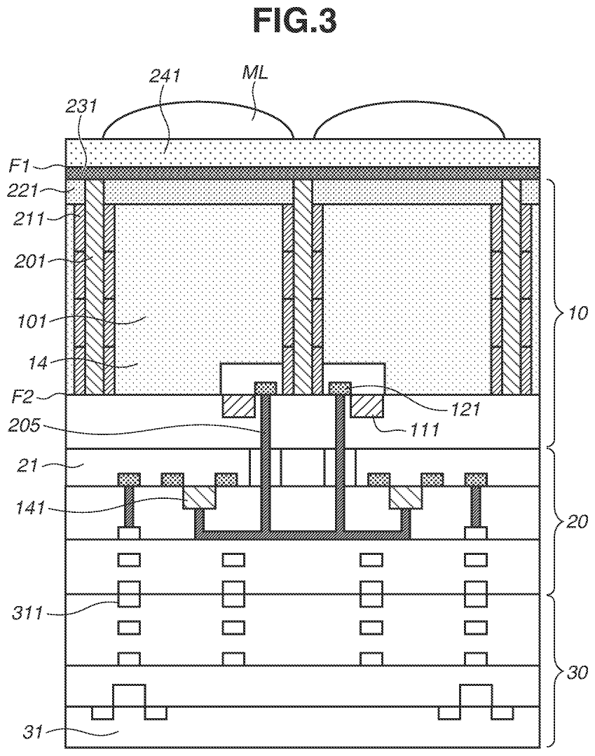

FIG. 3 is a cross-sectional view illustrating the photoelectric conversion apparatus according to the present exemplary embodiment. The cross-sectional view illustrates a cross section of the first component 10, the second component 20, and the third component 30 taken along a line passing through the photodiodes PD and the gates of the transfer transistors TR. Semiconductor regions 101 are the photodiodes PD. In other words, each semiconductor region 101 is a photoelectric conversion region in which signal charges (electrons according to the present exemplary embodiment) are generated based on incident light and the generated signal charges are accumulated. Further, each semiconductor region 101 is an N-type impurity region. In the structure illustrated in FIG. 2, four sensor portions 12 are connected to one amplifier transistor AMP. In the cross-sectional view in FIG. 3, two sensor portions 12 that appear on one cross section are illustrated among the four sensor portions 12.

Transfer gates 111 of the transfer transistors TR control conduction between the semiconductor regions 101 and semiconductor regions 121 (first semiconductor region), which are regions of the first FD nodes FD1. The semiconductor regions 121 are N-type semiconductor regions. Pixel separator portions 201 are disposed between the plurality of semiconductor regions 101 of the plurality of sensor portions 12 and electrically separate the plurality of semiconductor regions 101. The pixel separator portions 201 may contain an insulator portion, such as silicon oxide, or may be semiconductor regions forming a potential barrier. The pixel separator portions 201 are typically semiconductor regions where charges opposite in polarity to the signal charges accumulated in the photodiodes PD are main carriers. Pixel separator layers 211 are disposed between the pixel separator portions 201 and the semiconductor regions 101. The pixel separator layers 211 have a role of reducing a dark current especially in a case where the pixel separator portions 201 are configured with an insulator portion. The semiconductor regions 121, which are the first FD nodes FD1, and the gates 141 of the amplifier transistors AMP are connected together via conductors 205. The conductors 205 mainly contain metals, such as tungsten and copper. The conductors 205 are formed to penetrate insulators 251 separating the semiconductor substrate 21. The insulators 251 electrically separate the plurality of read circuits 22 from each other. Further, the insulators 251 are each provided to penetrate from a third surface F3 of the semiconductor substrate 21 to a fourth surface F4 of the semiconductor substrate 21.

The semiconductor substrate 14 has a first surface F1 on an incidence side and a second surface F2 opposite the first surface F1. A semiconductor region 221 is a P-type semiconductor region disposed in a region on the first surface F1 (the incidence side) of the semiconductor region 101. A fixed charge film 231 is provided on the first surface F1 of the semiconductor substrate 14. The semiconductor region 221 and the fixed charge film 231 reduce a dark current entering the semiconductor region 101.

Microlenses ML guide light to the semiconductor regions 101. Between the microlenses ML and the fixed charge film 231 are disposed a planarization layer 241. Each of the plurality of sensor portions 12 may be provided with a color filter to perform color separation.

The first component 10, the second component 20, and the third component 30 are stacked. The second component 200 is disposed between the first component 100 and the third component 300. The semiconductor substrate 31 of the third component 300 includes transistors 301. The second component 20 and the third component 30 are electrically connected together via connector portions 311. The connector portions 311 are formed using metals. Typically, the connector portions 311 mainly contain copper. Further, the connector portions 311 further contain a barrier metal (titanium, nickel, etc.) to prevent copper diffusion.

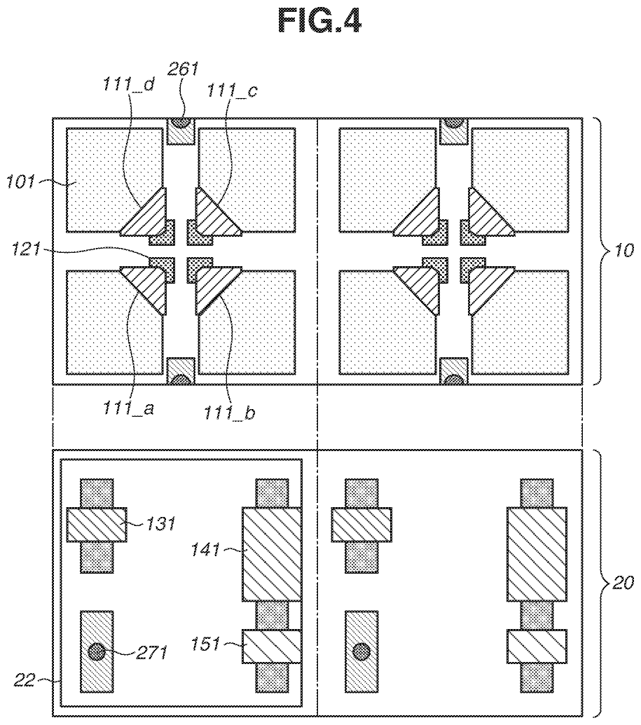

FIG. 4 is a combination of a plan view illustrating the second surface F2 of the first component 10 in FIG. 3 as viewed from the second component 20 and a plan view illustrating the second component 20 as viewed from the third component 30 in the photoelectric conversion apparatus illustrated in FIGS. 2 and 3.

In FIG. 4, each member having a similar function to its corresponding member in FIGS. 2 and 3 is given the same reference numeral as in FIGS. 2 and 3. The transfer gates 111_a to 111_d are each provided to the respective four semiconductor regions 101, which are the photodiodes PD. The two transfer gates 111_a and 111_c are disposed opposite. Further, the two transfer gates 111_b and 111_d are disposed opposite. Each of the transfer gates 111_a to 111_d is provided with the corresponding semiconductor region 121, which is the first FD node FD1.

Further, well contacts 261 are provided to apply a predetermined potential (typically ground potential) to the well regions of the semiconductor substrate 14 of the first component 10.

The gates 141 of the amplifier transistors AMP and the gates 151 of the selection transistors SEL are provided to the semiconductor substrate 21 of the second component 20. Further, the gates 131 of the reset transistors RES are also provided. Further, well contacts are provided to apply a predetermined potential (typically ground potential) to well regions of the semiconductor substrate 21 of the second component 20.

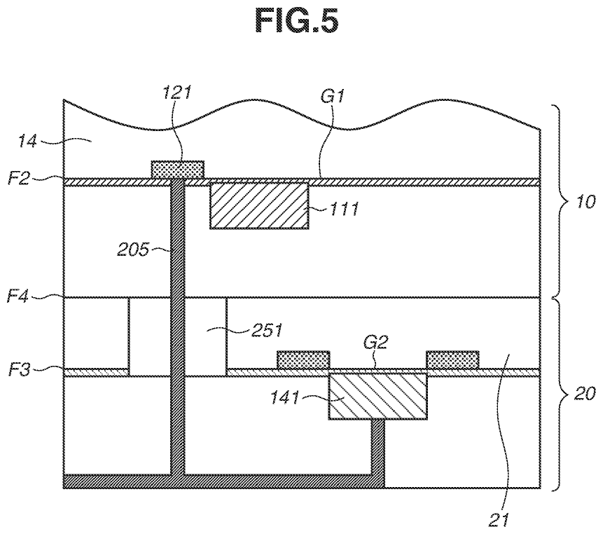

FIG. 5 is a cross-sectional view illustrating the semiconductor substrate 14 of the first component 10 and the semiconductor substrate 21 of the second component 20. Between the second surface F2 of the semiconductor substrate 14 and the transfer gate 111 is disposed a gate insulator film G1 (first gate insulator film). Further, the semiconductor substrate 21 has the third surface F3 and the fourth surface F4 opposite the third surface F3. Between the third surface F3 of the semiconductor substrate 21 and the gate 141 of the amplifier transistor AMP is disposed a gate insulator film G2 (second gate insulator film). Similarly, the gate insulator film G2 (second gate insulator film) is also provided between the third surface F3 of the semiconductor substrate 21 and the gate of the reset transistor RES. Furthermore, the gate insulator film G2 (second gate insulator film) is also provided between the third surface F3 of the semiconductor substrate 21 and the gate of the selection transistor SEL.

Each of the gate insulator films G1 and G2 is typically a film that mainly contains silicon and oxygen or a film that mainly contains silicon and nitrogen. In other words, each of the gate insulator films G1 and G2 may be a silicon oxide film, a silicon oxynitride film, or a silicon nitride film.

According to the present exemplary embodiment, the gate insulator films G1 and G2 are differentiated in relative permittivity. Meanwhile, the gate insulator films G1 and G2 are substantially equal in film thickness to each other. The phrase “substantially equal” indicates that variations in film thickness resulting from errors caused by manufacturing variations are allowed. Further, according to the present exemplary embodiment, the gate insulator film G2 is higher in relative permittivity than the gate insulator film G1. This improves a drive force of the amplifier transistors AMP. In contrast, making the gate insulator film G1 lower in relative permittivity than the gate insulator film G2 prevents the formation of a strong electric field in a semiconductor region under the transfer gate 111. This reduces a leakage current occurring near the transfer gate 111, so that noise is reduced. The gate insulator films G1 and G2 are enabled to be differentiated in relative permittivity by, for example, a nitrogen concentration being differentiated from each other. Specifically, in order to increase a relative permittivity of a gate insulator film, a nitrogen concentration of the gate insulator film is increased. Thus, according to the present exemplary embodiment, the gate insulator film G1 is higher in nitrogen concentration than the gate insulator film G2, thus differentiating the relative permittivity between the gate insulator films G1 and G2. In this example case, the gate insulator film G1 can be a silicon oxynitride film or a silicon nitride film, and the gate insulator film G2 can be a silicon oxide film.

The relative permittivity of gate insulator films may be differentiated with a method other than the method of differentiating nitrogen concentrations. For example, the gate insulator films G1 and G2 may include the same chemical elements and have a different film density from each other. Decreasing a film density of a gate insulator film reduces a relative permittivity of the gate insulator film. Thus, the gate insulator film G1 has a smaller film density than the film density of the gate insulator film G2. Thus, the gate insulator film G2 has a higher relative permittivity than the relative permittivity of the gate insulator film G1. Further, the gate insulator films G1 and G2 may have a different film density and a different nitrogen concentration from each other. The relative permittivity of the gate insulator film G2 may be made higher than the relative permittivity of the gate insulator film G1 by differentiating film densities and nitrogen concentrations. In this case, the film density of the gate insulator film G2 is made smaller than the film density of the gate insulator film G1 while the nitrogen concentration of the gate insulator film G2 is made higher than the nitrogen concentration of the gate insulator film G1. This makes the relative permittivity of the gate insulator film G2 higher than the relative permittivity of the gate insulator film G1. Further, while the gate insulator film G1 is higher in nitrogen concentration than the gate insulator film G2, the gate insulator film G2 is made higher in film density than the gate insulator film G1. Thus, the gate insulator film G2 has a higher relative permittivity than the relative permittivity of the gate insulator film G1.

According to the present exemplary embodiment, the transfer transistors TR and the amplifier transistors AMP are provided in a different semiconductor substrate. This makes it possible for the gate insulator films G1 and G2 to have a different relative permittivity. According to the present exemplary embodiment, the gate insulator film G1 is made lower in relative permittivity than the gate insulator film G2. This makes it possible to realize both increase in drive force of the amplifier transistors AMP and noise reduction of the transfer gates 111.

While four photodiodes PD sharing one second FD node FD2 has been described in the present exemplary embodiment, this is not restrictive. Specifically, more than four photodiodes PD may share one second FD node FD2.

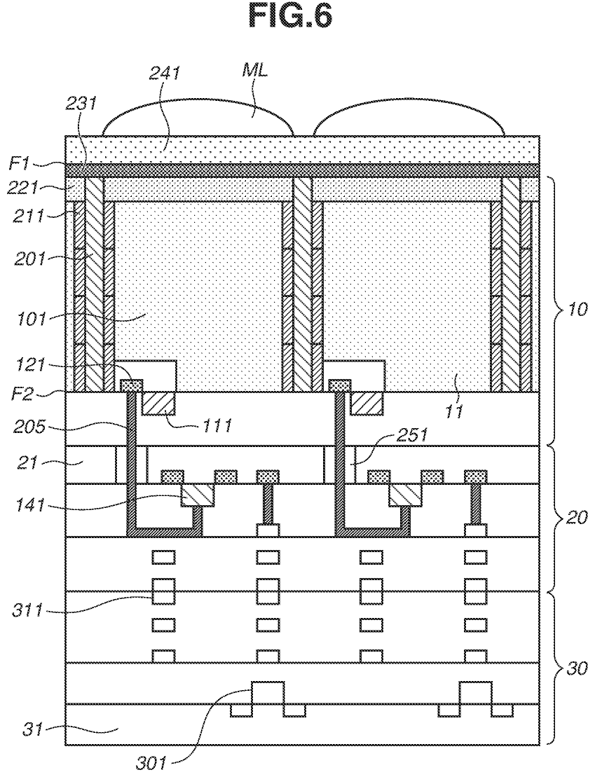

Further, one photodiode PD may be connected to one second FD node FD2 as illustrated in FIG. 6. FIG. 6 illustrates a structure in which only one photodiode PD is connected to the gate 141 of one amplifier transistor AMP, which is the second FD node FD2. In FIG. 6, each member having a similar function to its corresponding member in FIG. 3 is given the same reference numeral as the corresponding member, and redundant descriptions thereof are omitted.

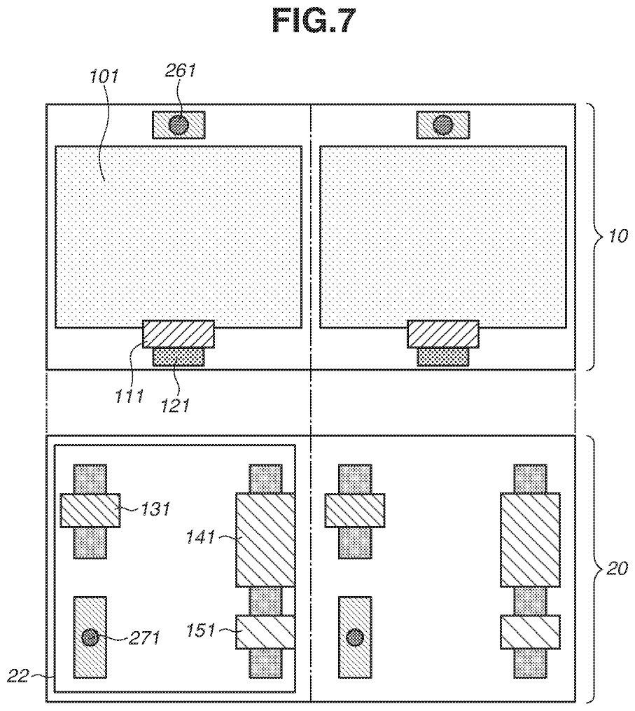

FIG. 7 is a plan view illustrating a structure in which only one photodiode PD is connected to one second FD node FD2 illustrated in FIG. 6. This plan view is a combination of a plan view illustrating the second surface F2 of the first component 10 as viewed from the second component 20 and a plan view illustrating the second component 20 as viewed from the third component 30, as in FIG. 4.

In FIG. 7, each member having a similar function to its corresponding member in FIG. 4 is given the same reference numeral as the corresponding member in FIG. 4. A transfer gate 111 is provided to one semiconductor region 101, which is the photodiode PD. One semiconductor region 101 and one semiconductor region 121, which is the first FD node FD1, are connected to the gate 141 of each amplifier transistor AMP of one read circuit 22. In also this structure, an advantage effect similar to that produced by the present exemplary embodiment is produced with the gate insulator films G1 and G2 having a different relative permittivity as in the present exemplary embodiment.

A second exemplary embodiment will be described below, focusing mainly on differences from the first exemplary embodiment.

According to the present exemplary embodiment, the gate insulator films G1 and G2 are differentiated in relative permittivity and are differentiated also in film thickness. In particular, the gate insulator film G2 is made smaller in film thickness than the gate insulator film G1. This further improves the drive force of the amplifier transistors AMP. Furthermore, random telegraph signal (RTS) occurring in the amplifier transistors AMP is reduced.

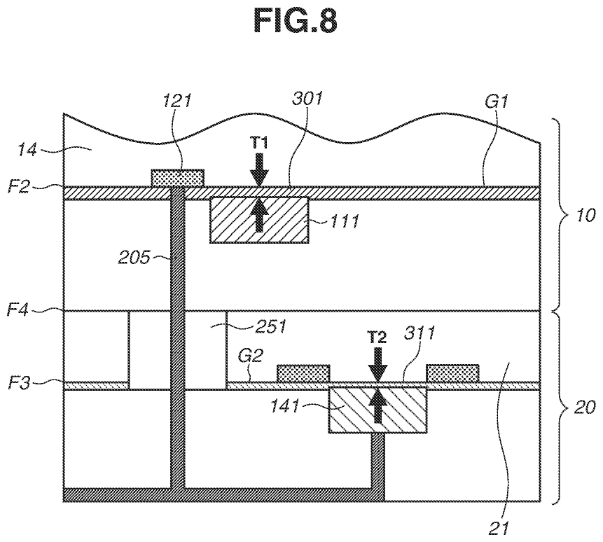

FIG. 8 is a cross-sectional view illustrating a photoelectric conversion apparatus according to the present exemplary embodiment. The photoelectric conversion apparatus according to present exemplary embodiment has a similar structure to those illustrated in FIGS. 2 to 4. The present exemplary embodiment is also applicable to the structures of the photoelectric conversion apparatus in FIGS. 6 and 7.

In FIG. 8, each member having a function similar to its corresponding member in FIG. 5 is given the same reference numeral as the corresponding member in FIG. 5.

According to the present exemplary embodiment, a film thickness T2 of the gate insulator film G2 is made smaller than a film thickness T1 of the gate insulator film G1. This further improves the drive force of the amplifier transistors AMP as described above. Further, RTS noise occurring in the amplifier transistors AMP is reduced. From another perspective, the gate insulator film G1 is made greater in film thickness than the gate insulator film G2. This weakens an electric field in a region under the transfer gate 111 in the semiconductor substrate 14. This produces an advantage effect of reducing a gate leakage current and a gate induced drain leakage current (GIDL).

The method of differentiating the gate insulator films G1 and G2 in relative permittivity in the first exemplary embodiment described above is also applicable to the present exemplary embodiment. Specifically, the gate insulator films G1 and G2 may contain a different main chemical element or may have a different film density.

A third exemplary embodiment will be described below, focusing mainly on differences from the second exemplary embodiment. In the present exemplary embodiment, the gate insulator films G1 and G2 are differentiated in relative permittivity and are also differentiated in film thickness. In particular, the gate insulator film G2 is made greater in film thickness than the gate insulator film G1. This enables suitable performance while preventing the layered components of the first component 10 and the second component 20 from separating.

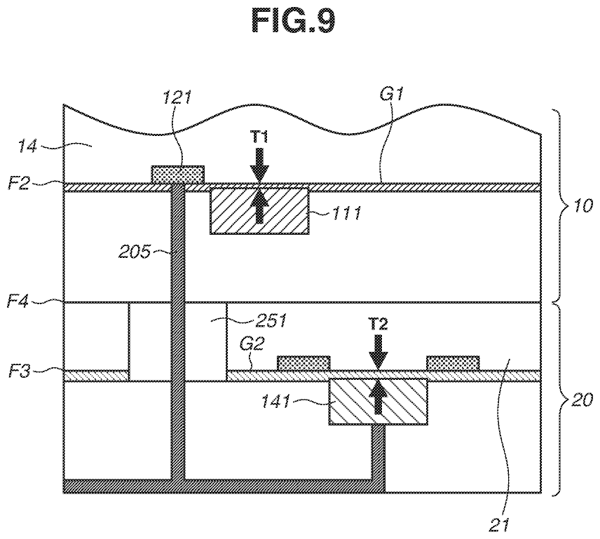

FIG. 9 is a cross-sectional view illustrating the photoelectric conversion apparatus according to the present exemplary embodiment. The photoelectric conversion apparatus according to the present exemplary embodiment has a similar structure to those illustrated in FIGS. 2 to 4. The present exemplary embodiment is also applicable to the structures of the photoelectric conversion apparatus illustrated in FIGS. 6 and 7.

In FIG. 9, each member having a similar function to its corresponding member in FIG. 5 is given the same reference numeral as the corresponding member in FIG. 5.

In the present exemplary embodiment, the film thickness T2 of the gate insulator film G2 is made greater than the film thickness T1 of the gate insulator film G1. In a process of stacking the first component 10 and the second component 20, thermal processing is sometimes applied. The thermal processing may cause excessive diffusion of impurities from the semiconductor region 101 of the photodiode PD. In order to reduce the thermal diffusion, the film thickness T2 of the gate insulator film G2 is increased. This reduces heat from the second component 20 to the first component 10. Further, increasing the film thickness T2 of the gate insulator film G2 reduces the occurrence of separation of the stacked components of the first component 10 and the second component 20.

Further, the gate insulator films G1 and G2 may have a relationship of relative permittivity similar to that in the first exemplary embodiment. This produces an advantage effect similar to that produced by the first exemplary embodiment.

Further, the relationship of relative permittivity between the gate insulator films G1 and G2 may be the opposite of that in the first exemplary embodiment, in other words, the gate insulator film G2 has a smaller relative permittivity than that of the gate insulator film G1. In this case, low pressure chemical vapor deposition (LP-CVD) is applicable to a process of forming the gate insulator film G2. This makes it possible to form the gate insulator film G2 through a process conducted at lower temperature as compared to a case where the gate insulator film G2 is formed with a thermal oxidation method. Further, a gate insulator film formed through the LP-CVD method is lower in film density than a gate insulator film formed by the thermal oxidation method. Thus, the use of the LP-CVD method enables the gate insulator film G2 to have a smaller relative permittivity than the relative permittivity of the gate insulator film G1. Further, in a case where the gate insulator film G2 is formed using the LP-CVD method, since the film density is smaller than the film density in the case where the thermal oxidation method is used, a gate withstand voltage (electric withstand voltage) may become insufficient. In such a case, making the film thickness T2 of the gate insulator film G2 greater than the film thickness T1 of the gate insulator film G1 as in the present exemplary embodiment secures a sufficient gate withstand voltage.

A photoelectric conversion apparatus according to a fourth exemplary embodiment will be described below, focusing mainly on differences from the first exemplary embodiment.

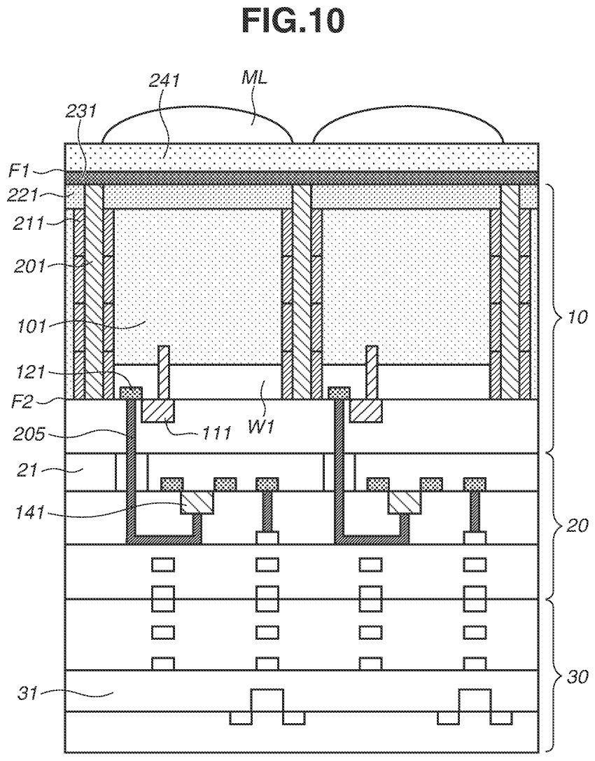

A structure according to the present exemplary embodiment is illustrated in FIG. 10. In the structure illustrated in FIG. 10, one semiconductor region 101 is connected to one second FD node FD2 as in the structure illustrated in FIG. 6. Further, in the structure in FIG. 10, each transfer gate 111 extends from the second surface F2 of the semiconductor substrate 14 to penetrate a corresponding well layer W1 and reach the corresponding semiconductor region 101 of the corresponding photodiode PD. This structure increases saturation charge of the photodiode PD based on a PN junction of the well layer W1 and the semiconductor region 101. Further, since the transfer gates 111 penetrate the well layers W1 and reaches the semiconductor regions 101, signal charges from the photodiodes PD are transferred to the semiconductor regions 121 at high speed.

A photoelectric conversion apparatus according to a fifth exemplary embodiment will be described below, focusing mainly on differences from the first exemplary embodiment.

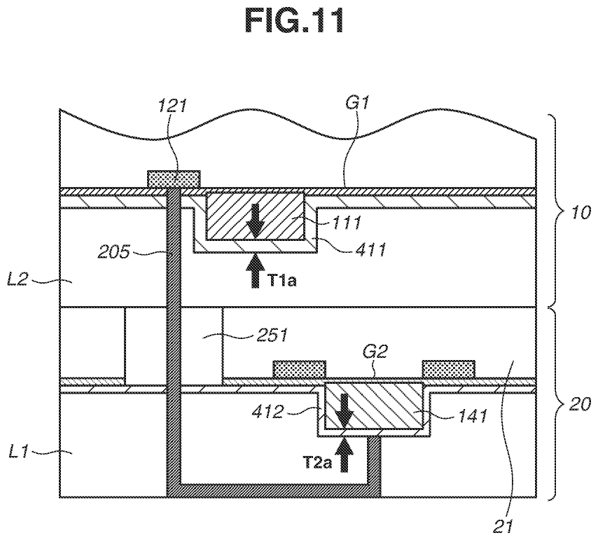

FIG. 11 is a cross-sectional view illustrating the photoelectric conversion apparatus according to the present exemplary embodiment. The photoelectric conversion apparatus according to the present exemplary embodiment has a structure similar to those illustrated in FIGS. 2 to 4. The present exemplary embodiment is also applicable to the structures of the photoelectric conversion apparatus illustrated in FIGS. 6 and 7.

In FIG. 11, each member having a function similar to its corresponding member in FIG. 5 is given the same reference numeral as the corresponding member in FIG. 5.

The photoelectric conversion apparatus according to the present exemplary embodiment includes a protective film 411 (first protective film) covering the transfer gate 111 and a protective film 412 (second protective film) covering the gate of the amplifier transistor AMP 141, and the protective films 411 and 412 are different in film thickness. A film thickness T1a of the protective film 411 (first protective film) covering the transfer gate 111 is made greater than a film thickness T2a of the protective film 412 (second protective film) covering the gate of the amplifier transistor AMP 141. Each of the protective films 411 and 412 is typically a film that mainly contains silicon and nitrogen, typically a silicon nitride film. The protective film 411 functions as an etch stop film in penetration for the conductor 205. Here, the conductor 205 is to be processed to penetrate through an insulator film L1 of the second component 20, the insulator 251 disposed in the semiconductor substrate 21, and an insulator film L2 of the first component 10. Thus, the protective film 411 that is thicker than the protective film 412 produces an advantage effect that the semiconductor region 121 is less likely to be damaged.

According to the present exemplary embodiment, the gate insulator films G1 and G2 are differentiated in relative permittivity as in the first exemplary embodiment. Thus, the advantage effect produced in the first exemplary embodiment is also produced in the present exemplary embodiment.

A sixth exemplary embodiment will be described below, focusing mainly on differences from the first exemplary embodiment. In a structure according to the present exemplary embodiment, the transfer gates 111 are made thicker than the gates of the amplifier transistors AMP 141.

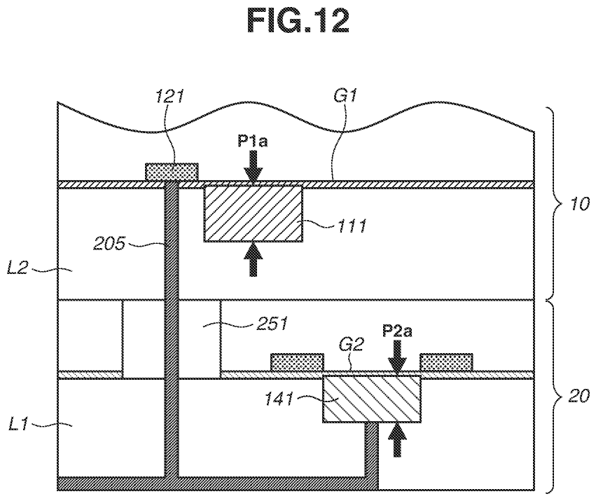

The present exemplary embodiment will be described below. The structure according to the present exemplary embodiment includes the structures illustrated in FIGS. 2 to 4 and is also applicable to the structures illustrated in FIGS. 6 and 7. FIG. 12 is a cross-sectional view illustrating a photoelectric conversion apparatus according to the present exemplary embodiment. According to the present exemplary embodiment, a thickness P1a of the transfer gate 111, which is the gate of the transfer transistor TR, is made thicker than a thickness P2a of the gate of the amplifier transistor AMP 141.

A contact plug to be connected to the transfer gate 111 is formed through an etching process similar to an etching process for forming the conductor 205. Through this process, a deep contact hole is formed as in the process of forming the conductor 205. This may cause etching damage to the transfer gate 111. To address this, according to the present exemplary embodiment, the transfer gate 111 is made thicker than the gate of the amplifier transistor AMP 141. This structure reduces effects of the etching damage even if there is etching damage to the transfer gate 111, as compared to a case where the transfer gate 111 is formed with the thickness P2a. This produces an advantage effect of securing the reliability of the transfer gate 111 of the photoelectric conversion apparatus of the present exemplary embodiment.

Not only the present exemplary embodiment but also the other exemplary embodiments may be combined with another exemplary embodiment as appropriate. The present exemplary embodiment may be combined with the second to fifth exemplary embodiments as appropriate.

A seventh exemplary embodiment will be described below, focusing mainly on differences from the first exemplary embodiment.

A photoelectric conversion apparatus according to the present exemplary embodiment may have a structure similar to that in the first exemplary embodiment.

The vertical scan circuits 42 provide control signals VTX_a to VTX_d to the transfer transistors TR_a to TR_d illustrated in FIG. 2. The control signals VTX_a to VTX_d have at least two voltage levels. The transfer transistors TR herein are N-type MOS transistors. In response to an input of a control signal VTX of a relatively high voltage, the transfer transistor TR is turned on. Thus, signal charges from the corresponding photodiode PD are transferred to the corresponding first FD node FD1. In contrast to this, in response to an input of a control signal VTX of a relatively low voltage, the transfer transistor TR is turned off. Thus, the corresponding photodiode PD and the corresponding first FD node FD1 becomes nonconductive. The phrase “nonconductive” is not limited to no flow of any currents and, for example, flow of a leakage current is encompassed within the scope of the “nonconductive”. The amplitude of the control signal VTX is considered as the difference between the voltage of the control signal VTX and the reference voltage. The reference voltage is, for example, the voltage applied to the well region of the photodiode PD (typically the ground potential). In other words, the amplitude of the control signal VTX for turning on the transfer transistor TR is expressed with a difference between the well potential of the photodiode PD and the relatively high voltage of the control signal VTX. In contrast, the amplitude of the control signal VTX for turning off the transfer transistor TR is expressed with a difference between the well potential of the photodiode PD and the relatively low voltage of the control signal VTX. While the well potential of the photodiode PD is described above as the reference voltage for the amplitude, another perspective is also possible. Specifically, a voltage of the control signal VTX for turning off the transfer transistor TR may be regarded as the reference voltage. In this case, the amplitude of the control signal VTX for turning on the transfer transistor TR is a difference between a voltage of the control signal VTX for turning on the transfer transistor TR and the voltage of the control signal VTX for turning off the transfer transistor TR.

Here, the transfer transistors TR have been described above as N-type MOS transistors. As described above, the conductivity types of transistors in the present specification may be changed as appropriate. Naturally, the transfer transistor TR may be a P-type MOS transistor.

In a case where the transfer transistor TR is a P-type MOS transistor, the transfer transistor TR is turned on with the control signal VTX of a relatively low voltage. In contrast, the transfer transistor TR is turned off with the control signal VTX of a relatively high voltage. In this case, a relationship becomes alike to one described above from a perspective as an amplitude from the reference voltage. Specifically, in a case where the well potential (typically a positive voltage of about 3 V) of the photodiode PD is regarded as the reference voltage, the amplitude of the control signal VTX for turning on the transfer transistor TR becomes greater than the amplitude (the difference from the reference voltage) of the control signal VTX for turning off the transfer transistor TR. Similar relationship is applied to a case where the potential of the control signal VTX for turning off the transfer transistor TR is regarded as the reference voltage.

Specifically, the amplitude (the difference from the reference voltage) of the control signal VTX for turning on the transfer transistor TR is greater than the amplitude (the difference from the reference voltage) of the control signal VTX for turning off the transfer transistor TR. Hereinafter, unless otherwise specified, an amplitude will be described as a difference from the reference voltage.

According to the present exemplary embodiment, the amplitude of the control signal VTX for turning on the transfer transistor TR is made greater than the amplitude of the power supply voltage SVDD, which is a voltage applied to a main node of the reset transistor RES. While the transfer transistor TR is described as an N-type MOS transistor, the control signal VTX for turning on the transfer transistor TR is set to 5 V. Meanwhile, the power supply voltage SVDD is set to 3 V. Specifically, in a case where the well potential (ground potential) of the photodiode PD is set to the reference voltage, the control signal VTX for turning on the transfer transistor TR is greater in amplitude than the power supply voltage SVDD. Further, a description will be provided of a case where the reference voltage is set to the voltage of the control signal VTX for turning off the transfer transistor TR. The voltage of the control signal VTX for turning off the transfer transistor TR is set to −1 V. The control signal VTX for turning on the transfer transistor TR is greater in amplitude than the power supply voltage SVDD also in the case where the reference voltage is set to the voltage of the control signal VTX for turning off the transfer transistor TR. While the voltage of the control signal VTX for turning off the transfer transistor TR is described above as −1 V, a different voltage, such as a ground potential, may be used. Further, as described above, the control signal VTX for turning on the transfer transistor TR is greater in amplitude than the power supply voltage SVDD also in a case where the transfer transistor TR is a P-type MOS transistor.

While two values are described above as possible values of the control signal VTX, further different voltage values may be set to the control signal VTX. For example, an overflow of signal charges from the photodiode PD to the first FD node FD1 may occur during a period in which the photodiode PD accumulates signal charges. In this case, the control signal VTX may be adjusted between on and off levels of the transfer transistor TR during the period.

According to the present exemplary embodiment, the gate insulator films G1 and G2 are substantially equal in film thickness. The phrase “substantially equal” indicates that variations in film thickness resulting from errors caused by manufacturing variations are allowed. Each film thickness of the gate insulator films G1 and G2 is determined based on the gate withstand voltage required for the transfer transistor TR.

According to the present exemplary embodiment, the control signal VTX for turning on the transfer transistor TR is greater in amplitude than the power supply voltage SVDD, which is the voltage applied to the main node of the reset transistor RES. Effects thereof will be described below.

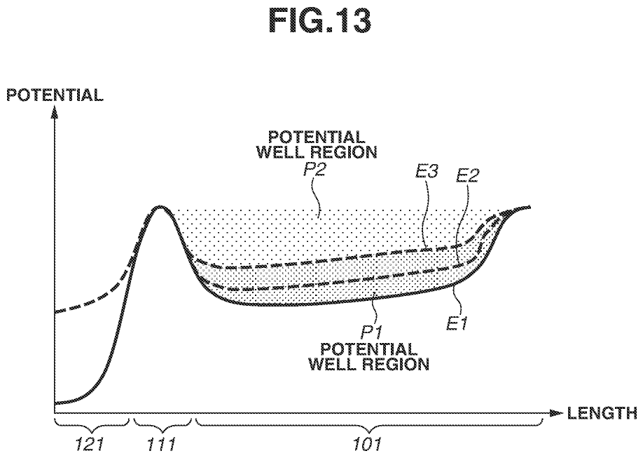

In FIG. 13, a horizontal axis represents lengths from the semiconductor region 121, and a vertical axis represents potentials with respect to signal charges (here, electrons) accumulated by the photodiode PD.

A potential curve E1 is a curve in a case where the power supply voltage SVDD is set to 5 V, in other words, a case where the floating diffusion FD is reset with a voltage obtained by subtracting the threshold for the reset transistor RES from 5 V. The photodiode PD is also reset to a voltage corresponding to the reset voltage of the floating diffusion FD. A potential curve E2 is a curve in a case where the power supply voltage SVDD is set to 3 V, in other words, a case where the floating diffusion FD is reset with a voltage obtained by subtracting the threshold for the reset transistor RES from 3 V. The photodiode PD is also reset to a voltage corresponding to the reset voltage of the floating diffusion FD. Decreasing the power supply voltage SVDD increases the potential of the photodiode PD, and the potential curve E2 is obtained. Further, as the power supply voltage SVDD is decreased, transfer characteristics of the transfer transistor TR decrease. Thus, further decreasing an impurity concentration of the photodiode PD may be considered. In this case, the potential curve of the semiconductor region 101 further increases, and a curve E3 is obtained.

As a result, as the power supply voltage SVDD is decreased, the saturation charge of the photodiode PD decreases from an amount of a potential well region P1 to an amount of a potential well region P2. Thus, realizing both the reduction of the power supply voltage SVDD and the saturation charge of the photodiode PD is an issue.

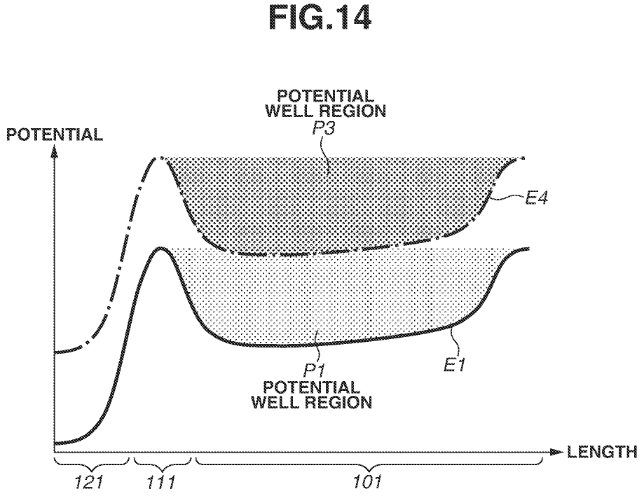

According to the present exemplary embodiment, the control signal VTX for turning on the transfer transistor TR is made greater in amplitude than the power supply voltage SVDD, which is the voltage applied to the main node of the reset transistor RES. A potential curve obtained with this form is illustrated in FIG. 14.

The potential well region P1 is the same as that in FIG. 13. A curve E4 is a potential curve according to the present exemplary embodiment. The control signal VTX for turning on the transfer transistor TR is made greater in amplitude than the power supply voltage SVDD, which is the voltage applied to the main node of the reset transistor RES. This makes it possible to secure a sufficient potential barrier under the transfer gate 111 even in a case where the power supply voltage SVDD is decreased. Thus, a sufficient saturation charge as a potential well region P3 is realized also in the case of the curve E4. In the form illustrated in FIG. 14, the saturation charges in the potential well regions P1 and P3 are at a substantially equal level. This enables the photoelectric conversion apparatus according to the present exemplary embodiment to realize both the reduction of the power supply voltage SVDD and a high saturation charge of the photodiode PD.

According to the present exemplary embodiment, a common film thickness is set to the gate insulator films G1 and G2 based on the gate withstand voltage required for the transfer transistor TR. Specifically, a common film thickness is set to the gate insulator film G1 of the transfer transistor TR and the gate insulator film G2 of the amplifier transistor AMP, the reset transistor RES, and the selection transistor SEL, which are transistors of the second component 20. In other words, the gate insulator films G1 and G2 have the same film thickness. This makes it possible to obtain a sufficient gate withstand voltage also for transistors of the second component 20.

The gate insulator films G1 and G2 may have a different film thickness. The gate withstand voltages of the amplifier transistor AMP, the reset transistor RES, and the selection transistor SEL may be lower in level than the transfer transistor TR to which the control signal VTX greater in amplitude than the power supply voltage SVDD is applied. Thus, the gate insulator film G2 of the transistors of the second component 20 may be thinner than the gate insulator film G1 of the transfer transistor TR.

While four photodiodes PD share one second FD node FD2 in the above-described form according to the present exemplary embodiment, the present exemplary embodiment is not limited to the form. Specifically, more than four photodiodes PD may share one second FD node FD2.

Further, as illustrated in FIGS. 6 and 7, one photodiode PD may be connected to one second FD node FD2. In the structures illustrated in FIGS. 6 and 7, one photodiode PD is connected to the gate 141 of one amplifier transistor AMP, which is the second FD node FD2. The above-described form according to the present exemplary embodiment in which the control signal VTX for turning on the transfer transistor TR is made greater in amplitude than the power supply voltage SVDD, which is a voltage applied to a main node of the amplifier transistor AMP, is also applicable to the structures illustrated in FIGS. 6 and 7. This produces an advantage effect similar to the above-described advantage effect of the present exemplary embodiment.

Further, while the voltage to be applied to the main node of the amplifier transistor AMP and the voltage to be applied to the main node of the reset transistor RES are both the same power supply voltage SVDD according to the present exemplary embodiment, the present exemplary embodiment is not limited to this example. Specifically, different power supply voltages may be supplied to the main node of the amplifier transistor AMP and the main node of the reset transistor RES. In this case, the control signal VTX greater in amplitude than at least one of a first power supply voltage of the main node of the reset transistor RES and a second power supply voltage of the main node of the amplifier transistor AMP is to be applied in turning on the transfer transistor TR. In particular, it is desirable the control signal VTX greater in amplitude than the first power supply voltage that is to be applied to the main node of the reset transistor RES is applied with the transfer transistor TR is an on state, because a decrease in saturation charge of the photodiode PD is prevented.

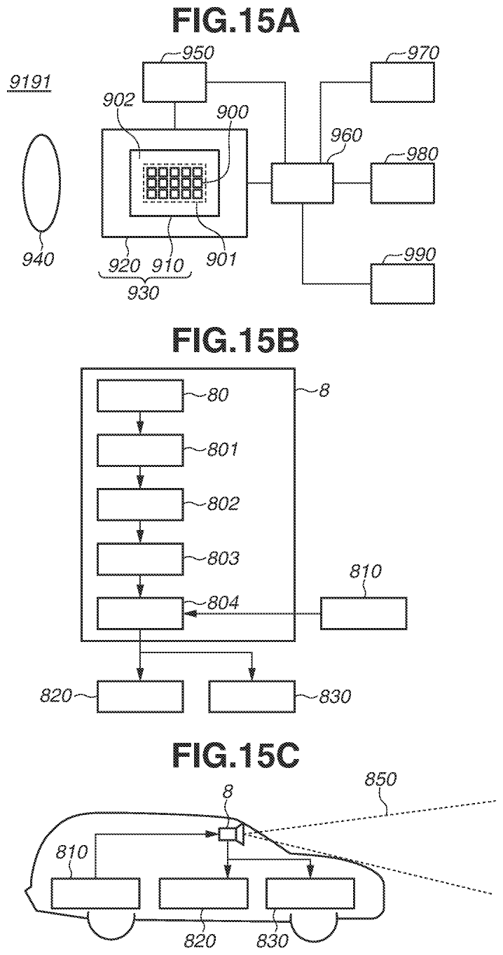

An eighth exemplary embodiment is applicable to any one of the first to seventh exemplary embodiments. FIG. 15A is a schematic diagram illustrating equipment 9191 including a semiconductor apparatus 930 according to the present exemplary embodiment. The semiconductor apparatus 930 may use any of the photoelectric conversion apparatuses (imaging apparatuses) according to the exemplary embodiments described above. The equipment 9191 including the semiconductor apparatus 930 will be described in detail below. As described above, the semiconductor apparatus 930 may include a package 920 storing a semiconductor device 910 in addition to the semiconductor device 910 including a semiconductor layer. The package 920 may include a base member to which the semiconductor device 910 is fixed and a cover member, such as a glass, facing the semiconductor device 910. The package 920 may further include bonding members, such as bonding wires and bumps, for connecting terminals provided to the base member and terminals provided to the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 is, for example, a lens, a shutter, and a mirror. The control apparatus 950 controls the semiconductor apparatus 930. The control apparatus 950 is a semiconductor apparatus, such as an application- specific integrated circuit (ASIC).

The processing apparatus 960 processes signals output from the semiconductor apparatus 930. The processing apparatus 960 is a semiconductor apparatus, such as a central processing unit (CPU) and an ASIC, for forming an analog front-end (AFE) or a digital front-end (DFE). The display apparatus 970 is an electroluminescent (EL) display apparatus or a liquid crystal display apparatus for displaying information (image) acquired by the semiconductor apparatus 930. The storage apparatus 980 is a magnetic device or a semiconductor device for storing information (image) acquired by the semiconductor apparatus 930. The storage apparatus 980 is a volatile memory, such as a static random access memory (SRAM) and a dynamic random access memory (DRAM), or a non-volatile memory, such as a flash memory and a hard disk drive.

The mechanical apparatus 990 includes a movable unit and/or a propulsion unit, such as a motor and an engine. In the equipment 9191, signals output from the semiconductor apparatus 930 are displayed on the display apparatus 970 and/or are externally transmitted by a communication apparatus (not illustrated) of the equipment 9191. Thus, the equipment 9191 desirably includes the storage apparatus 980 and the processing apparatus 960 separately from a storage circuit and a calculation circuit of the semiconductor apparatus 930. The mechanical apparatus 990 may be controlled by signals output from the semiconductor apparatus 930.

Further, the equipment 9191 is suitable for use in electronic equipment, such as an information terminal with an imaging function (e.g., smartphone, wearable terminal) and a camera (e.g., interchangeable lens camera, compact camera, video camera, monitoring camera). The mechanical apparatus 990 of a camera may drive components of the optical apparatus 940 for zooming, focusing, and shutter operations. Alternatively, the mechanical apparatus 990 of a camera can move the semiconductor apparatus 930 for anti-vibration operations.

Further, the equipment 9191 may be transportation equipment, such as a vehicle, a ship, and a flight vehicle. The mechanical apparatus 990 of transportation equipment may be used as a moving apparatus. The equipment 9191 as transportation equipment is suitable for use in something for transporting the semiconductor apparatus 930 or for assisting with and/or autonomous driving (control) using an imaging function. The processing apparatus 960 for assisting with and/or autonomous driving (control) may perform processing for operating the mechanical apparatus 990 as a moving apparatus based on information acquired by the semiconductor apparatus 930. Further, the equipment 9191 may be medical equipment, such as an endoscope, measurement equipment, such as a distance measurement sensor, analysis equipment, such as an electron microscope, office equipment, such as a copy machine, or industrial equipment, such as a robot.

The above-described exemplary embodiments make it possible to realize suitable pixel characteristics. This increases the semiconductor apparatus 930 in value. To increase the value herein refers to at least one of addition of a function, improvement in performance, improvement in characteristics, improvement in reliability, improvement in production yield, environmental load reduction, cost reduction, size reduction, and weight reduction.

Thus, use of the semiconductor apparatus 930 according to the present exemplary embodiment in the equipment 9191 improves the equipment 9191 in value. For example, the semiconductor apparatus 930 may be mounted on transportation equipment to realize excellent performance in imaging the outside of the transportation equipment or in measuring an external environment. Thus, determining to mount the semiconductor apparatus 930 according to the present exemplary embodiment on transportation equipment is advantageous in enhancing performance of the transportation equipment in manufacturing/selling the transportation equipment. The semiconductor apparatus 930 is suitable for use especially in assisting transportation equipment in driving using information acquired by the semiconductor apparatus 930 and/or in transportation equipment that performs autonomous driving using information acquired by the semiconductor apparatus 930.

A photoelectric conversion system and a movable body according to the present exemplary embodiment will be described below with reference to FIGS. 15B and 15C.

FIG. 15B illustrates an example of a photoelectric conversion system relating to an in-vehicle camera. A photoelectric conversion system 8 includes a photoelectric conversion apparatus 80. The photoelectric conversion apparatus 80 is any one of the photoelectric conversion apparatuses (imaging apparatuses) according to the above-described exemplary embodiments. The photoelectric conversion system 8 includes an image processing unit 801 and a parallax acquisition unit 802. The image processing unit 801 performs image processing on a plurality of pieces of image data acquired by the photoelectric conversion apparatus 80. The parallax acquisition unit 802 calculates parallax (phase difference between parallax images) from a plurality of pieces of image data acquired by the photoelectric conversion system 8. The photoelectric conversion system 8 further includes a length acquisition unit 803 and a collision determination unit 804. The length acquisition unit 803 calculates a length to a target object based on the calculated parallax. The collision determination unit 804 determines the likelihood of a collision based on the calculated length. The parallax acquisition unit 802 and the length acquisition unit 803 are an example of a length information acquisition unit configured to acquire length information to a target object. Specifically, the length information is parallax information, defocus amount information, or information about a length to a target object. The collision determination unit 804 may determine the likelihood of a collision using any one of the above-described pieces of length information. The length information acquisition unit may be realized by dedicated hardware or a software module. Further, the length information acquisition unit may be realized also by a field programmable gate array (FPGA), an ASIC, or a combination thereof.

The photoelectric conversion system 8 is connected to a vehicle information acquisition apparatus 810 and acquires vehicle information such as vehicle velocity, yaw rate, and rudder angle. Further, a control engine control unit (control ECU) 820 is connected to the photoelectric conversion system 8. The control ECU 820 is a control apparatus that outputs control signals for generating a braking force to a vehicle based on a determination result of the collision determination unit 804. Further, a warning apparatus 830 is also connected to the photoelectric conversion system 8. The warning apparatus 830 provides a warning to a driver based on a determination result of the collision determination unit 804. For example, in a case where the collision determination unit 804 determines that the likelihood of a collision is high, the control ECU 820 performs vehicle control to avoid a collision or reduce damage by applying a brake, releasing an accelerator, or reducing an engine output. The warning apparatus 830 warns a user by sounding a warning such as a sound, displaying warning information on a screen of a car navigation system, and/or vibrating a seatbelt and/or steering.

According to the present exemplary embodiment, the photoelectric conversion system 8 images surroundings of a vehicle, for example, an area ahead of or behind the vehicle.

FIG. 15C illustrates a photoelectric conversion system imaging an area ahead of a vehicle (imaging range 850). The vehicle information acquisition apparatus 810 transmits instructions to the photoelectric conversion system 8 or the photoelectric conversion apparatus 80. With this configuration, the distance measurement accuracy is further increased.

While the control for avoiding a collision with another vehicle is performed in the above-described example, applications to control for autonomous driving by following another vehicle or control for autonomous driving without driving beyond lanes are also possible. Furthermore, the photoelectric conversion system is applicable to not only vehicles but also moving objects (moving apparatuses) such as ships, aircraft, or industrial robots. Furthermore, the photoelectric conversion system is applicable to not only movable bodies but also equipment that widely uses object recognition such as intelligent transport systems (ITS).

### Modified Exemplary Embodiments

The present disclosure is not limited to the above-described exemplary embodiments, and various modifications can be made.

For example, an example in which part of a configuration according to one of the exemplary embodiments is added to another exemplary embodiment and an example in which part of a configuration according to one of the exemplary embodiments is replaced with part of a configuration according to another one of the exemplary embodiments are also included in the exemplary embodiments of the present disclosure.

Further, the equipment (photoelectric conversion system) according to the eighth exemplary embodiment is a mere example of a photoelectric conversion system to which the photoelectric conversion apparatus is applicable, and the photoelectric conversion system to which the photoelectric conversion apparatus according to an aspect of the present disclosure is applicable is not limited to the configuration illustrated in FIG. 13.

Each of the above-described exemplary embodiments merely illustrates a specific example of implementation of the present disclosure, and the technical scope of the present disclosure is not to be interpreted narrowly by the exemplary embodiments. Specifically, the present disclosure can be implemented in various forms without departing from the technical concept or major feature of the present disclosure.

The above-described exemplary embodiments can be changed as needed within the technical scope of the present disclosure. The disclosure of the present specification includes not only those described in the present specification but also those that can be understood from the present specification and those that can be understood from the drawings attached to the present specification. Further, the disclosure of the present specification includes complementary sets of concepts described in the present specification. Specifically, in a case where the present specification includes, for example, the description “A is greater than B”, it is understood that the present specification includes the disclosure “A is not greater than B” even in a case where the description “A is not greater than B” is omitted in the present specification because the inclusion of the description “A is greater than B” is based on the premise that the case where “A is not greater than B” is considered.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Applications No. 2022-091512, filed Jun. 6, 2022, and No. 2022-091514, filed Jun. 6, 2022, which are hereby incorporated by reference herein in their entirety.

What is claimed is:

1. A photoelectric conversion apparatus comprising:
a first component including a first semiconductor substrate having a first surface and a second surface opposite the first surface, a photoelectric conversion element configured to receive light from the first surface, a first semiconductor region, a transfer gate disposed on the second surface and configured to transfer a charge from the photoelectric conversion element to the first semiconductor region, and a first gate insulator film disposed between the second surface and the transfer gate; and
a second component stacked on the first component and including a second semiconductor substrate having a third surface and a fourth surface opposite the third surface, an amplifier transistor including a gate connected to the first semiconductor region, and a second gate insulator film between the gate and the third surface,
wherein the first gate insulator film and the second gate insulator film are different in relative permittivity.

2. The photoelectric conversion apparatus according to claim 1, wherein the second gate insulator film is greater in relative permittivity than the first gate insulator film.

3. The photoelectric conversion apparatus according to claim 1, wherein the first gate insulator film is greater in relative permittivity than the second gate insulator film.

4. The photoelectric conversion apparatus according to claim 1, wherein the first gate insulator film is smaller in film thickness than the second gate insulator film.

5. The photoelectric conversion apparatus according to claim 3, wherein the first gate insulator film is smaller in film thickness than the second gate insulator film.

6. The photoelectric conversion apparatus according to claim 1, wherein the first gate insulator film and the second gate insulator film are different in film density.

7. The photoelectric conversion apparatus according to claim 6, wherein the second gate insulator film is lower in film density than the first gate insulator film.

8. The photoelectric conversion apparatus according to claim 6, wherein the first gate insulator film is lower in film density than the second gate insulator film.

9. The photoelectric conversion apparatus according to claim 1, wherein the first gate insulator film and the second gate insulator film are different in nitrogen concentration.

10. The photoelectric conversion apparatus according to claim 9, wherein the second gate insulator film is higher in nitrogen concentration than the first gate insulator film.

11. The photoelectric conversion apparatus according to claim 1, wherein the first gate insulator film mainly contains silicon and oxygen, and the second gate insulator film mainly contains silicon and nitrogen.

12. The photoelectric conversion apparatus according to claim 1, comprising:
a first protective film covering the transfer gate; and
a second protective film covering the gate,
wherein the first protective film is greater in film thickness than the second protective film.

13. The photoelectric conversion apparatus according to claim 1, further comprising a third component including an analog-to-digital conversion unit configured to convert a signal output from the amplifier transistor into a digital signal, wherein the first component, the second component, and the third component are stacked.

14. The photoelectric conversion apparatus according to claim 1, comprising an insulator penetrating from one of the third surface and the fourth surface to another one of the third surface and the fourth surface, wherein the first semiconductor region and the gate are connected by a conductor penetrating the insulator.

15. The photoelectric conversion apparatus according to claim 1, wherein the transfer gate is thicker than the gate.

16. A photoelectric conversion apparatus comprising:
a first component including a first semiconductor substrate having a first surface and a second surface opposite the first surface, a photoelectric conversion element configured to receive light from the first surface, a first semiconductor region, and a transfer transistor including a transfer gate disposed on the second surface and configured to transfer a signal charge from the photoelectric conversion element to the first semiconductor region; and
a second component stacked on the first component and including a second semiconductor substrate having a third surface and a fourth surface opposite the third surface, an amplifier transistor including a gate connected to the first semiconductor region and disposed on the third surface, and a reset transistor configured to reset the gate,
wherein a difference between a voltage to be applied to the transfer gate during a period of the transfer of the signal charge from the photoelectric conversion element to the first semiconductor region and a reference voltage is greater than a difference between a power supply voltage to be applied to a main node of the reset transistor and the reference voltage.

17. A photoelectric conversion apparatus comprising:
a first component including a first semiconductor substrate having a first surface and a second surface opposite the first surface, a photoelectric conversion element configured to receive light from the first surface, a first semiconductor region, and a transfer transistor including a transfer gate disposed on the second surface and configured to transfer a signal charge from the photoelectric conversion element to the first semiconductor region; and
a second component stacked on the first component and including a second semiconductor substrate having a third surface and a fourth surface opposite the third surface, an amplifier transistor including a gate connected to the first semiconductor region and disposed on the third surface, and a reset transistor configured to reset the gate,
wherein a first power supply voltage is applied to a main node of the reset transistor, and a second power supply voltage is applied to a main node of the amplifier transistor, and
wherein a difference between a voltage to be applied to the transfer gate during a period of the transfer of the signal charge from the photoelectric conversion element to the first semiconductor region and a reference voltage is greater than at least one of a difference between the first power supply voltage and the reference voltage or a difference between the second power supply voltage and the reference voltage.

18. The photoelectric conversion apparatus according to claim 16,
wherein the photoelectric conversion element is formed inside a well region, and
wherein the reference voltage is a voltage to be applied to the well region.

19. The photoelectric conversion apparatus according to claim 17,
wherein the photoelectric conversion element is formed inside a well region, and
wherein the reference voltage is a voltage to be applied to the well region.

20. The photoelectric conversion apparatus according to claim 16, wherein the reference voltage is a voltage to be applied to the transfer gate during a period in which the transfer transistor is turned off.

21. The photoelectric conversion apparatus according to claim 17, wherein the reference voltage is a voltage to be applied to the transfer gate during a period in which the transfer transistor is turned off.

22. The photoelectric conversion apparatus according to claim 16,
wherein a first gate insulator film is disposed between the second surface and the transfer gate,
wherein a second gate insulator film is disposed between the third surface and the gate, and
wherein the first gate insulator film is greater in thickness than the second gate insulator film.

23. The photoelectric conversion apparatus according to claim 17,
wherein a first gate insulator film is disposed between the second surface and the transfer gate,
wherein a second gate insulator film is disposed between the third surface and the gate, and
wherein the first gate insulator film is greater in thickness than the second gate insulator film.

24. The photoelectric conversion apparatus according to claim 16,
wherein a first gate insulator film is disposed between the second surface and the transfer gate,
wherein a second gate insulator film is disposed between the third surface and the gate, and
wherein the first gate insulator film and the second gate insulator film are substantially equal in thickness to each other.

25. The photoelectric conversion apparatus according to claim 17,
wherein a first gate insulator film is disposed between the second surface and the transfer gate,
wherein a second gate insulator film is disposed between the third surface and the gate, and
wherein the first gate insulator film and the second gate insulator film are substantially equal in thickness to each other.

26. The photoelectric conversion apparatus according to claim 22, wherein the first gate insulator film and the second gate insulator film are different in relative permittivity.

27. The photoelectric conversion apparatus according to claim 26, wherein the first gate insulator film mainly contains silicon and oxygen, and the second gate insulator film mainly contains silicon and nitrogen.

28. The photoelectric conversion apparatus according to claim 16, further comprising a third component including an analog-to-digital conversion unit configured to convert a signal output from the amplifier transistor into a digital signal, wherein the first component, the second component, and the third component are stacked.

29. The photoelectric conversion apparatus according to claim 17, further comprising a third component including an analog-to-digital conversion unit configured to convert a signal output from the amplifier transistor into a digital signal, wherein the first component, the second component, and the third component are stacked.

30. An equipment comprising the photoelectric conversion apparatus according to claim 1, the equipment further comprising at least one of:
an optical apparatus compatible with the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store the information obtained by the photoelectric conversion apparatus; or
a mechanical apparatus configured to operate based on the information obtained by the photoelectric conversion apparatus.

31. An equipment comprising the photoelectric conversion apparatus according to claim 16, the equipment further comprising at least one of:
an optical apparatus compatible with the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store the information obtained by the photoelectric conversion apparatus; or
a mechanical apparatus configured to operate based on the information obtained by the photoelectric conversion apparatus.

32. An equipment comprising the photoelectric conversion apparatus according to claim 17, the equipment further comprising at least one of:
an optical apparatus compatible with the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store the information obtained by the photoelectric conversion apparatus; or
a mechanical apparatus configured to operate based on the information obtained by the photoelectric conversion apparatus.
